(19) United States
(12) Patent Application Publication
(10) Pub. No.: US 2004/0153878 A1
(43) Pub. Date: Aug. 5, 2004

(54) System and method for implementing a dynamic logger

(76) Inventors: Julian Bromwich, Calgary (CA); Ted Goddard, Calgary (CA); Calvin White, Calgary (CA)

Correspondence Address: Fay Kaplun & Marcin, LLP, Suite 702, 150 Broadway, New York, NY, 10038, US

(21) Appl. No.: 10/355,958

(22) Filed: Jan. 30, 2003

(51) Int. Cl. G06F 11/00; G11C 29/00

(52) U.S. Cl. 714/48; 714/723

(57) ABSTRACT

A logger system, comprising a core component configured to receive a log statement from an application program, the log statement including a group identifier and a level identifier, the core component further configured to direct a log report generated from the log statement to an output stream based on the group identifier and the level identifier of the log statement and log controls accessible to the core component.

### BACKGROUND INFORMATION

Examples of computing devices include personal computers (“PCs”), personal digital assistants (“PDAs”), embedded devices, etc. These computing devices contain processors or controllers that execute software programs in order to provide functionality to the users of the devices. Examples of application programs that may be loaded on these devices include word processing, web page display, electronic mail, control functionality software, etc.

Developers are constantly writing new application programs and improving existing application programs to provide additional functionality for users of the devices. During the development process, developers need to write and test the code to ensure that the application program is accomplishing its intended goals, is released with the fewest possible errors and is running as efficiently as possible. The software code for application programs may be thousands of lines of code with each section of code being written by a different developer or team of developers. Checking each line of code by hand would be virtually impossible due to the magnitude and complexity of the code. A debugging program aids a developer in searching the lines of code for errors or bugs and reports these errors to the developer. As part of this process, a logger program may be used to report on the activities that the application program is accomplishing while it is executing. The logger program may be a portion of another program (e.g., an operating system, a debugging program, a testing program, etc.) or a separate stand-alone program. The developer may use the reports (or logs) generated by the logger to correct or revise the application and continue to test the application program to determine if it is accomplishing the intended goals.

Similarly, the user of an application program may desire to know what is happening while the application program is executing. For example, if the application program does not complete its desired task, the user may desire to see a log indicating the error which prevented the application program from running to completion. Thus, there are many uses for log reports during both the development process of an application program and the running of an application program on a device.

### SUMMARY OF THE INVENTION

A logger system, comprising a core component configured to receive a log statement from an application program, the log statement including a group identifier and a level identifier, the core component further configured to direct a log report generated from the log statement to an output stream based on the group identifier and the level identifier of the log statement and log controls accessible to the core component.

A method comprising the steps of receiving a log statement from an application program, the log statement including a group identifier and a level identifier, accessing a log control which includes a group, a level and an output stream, comparing the group identifier and level identifier of the log statement to the corresponding group and level of the log control and directing a log report generated from the log statement to the output stream when the group of the log control includes the group identifier of the log statement and the level of the log control includes the level identifier of the log statement.

A system, comprising a log control component including log entry data, wherein each log entry includes a group, a level and an output stream and an arbitrator component receiving a log statement from an application program, the log statement including a group identifier and a level identifier, the arbitrator accessing each log entry and directing a log report generated from the log statement to the output stream of each log entry for which the group of the log entry includes the group identifier of the log statement and the level of the log entry includes the level identifier of the log statement.

### BRIEF DESCRIPTION OF DRAWINGS

FIG. 1 shows an exemplary embodiment of a dynamic logger system according to the present invention;

FIG. 2 shows an exemplary logical categorization of exemplary groups and levels for log statements according to the present invention;

FIG. 3 shows a diagram illustrating the use of a single instance of formatter components and device components to build multiple streams according to the present invention;

FIG. 4 shows an exemplary system for arbitrating between log statements and streams according to the present invention;

FIG. 5 shows an exemplary management component plug-in which provides a management interface for configuring the dynamic logger according to the present invention;

FIG. 6 shows an exemplary method for the arbitrator to direct the log reports to the appropriate stream according to the present invention.

### DETAILED DESCRIPTION

The present invention may be further understood with reference to the following description and the appended drawings, wherein like elements are provided with the same reference numerals. Throughout this specification the term logger will be used to refer to a software application which may form a portion of another software application or be a stand-alone application which provides the functionality of recording and/or reporting data on an application program which is being executed on a device. Exemplary data and methods of recording and/or reporting will be described in greater detail below. The application program may be any software program which may be executed by the processor(s) of the device. Also, throughout this description, the individual interacting with the exemplary embodiments of the dynamic logger according to the present invention will be described as a developer. However, those of skill in the art will understand that any person (assuming they are granted the requisite permission) may interact with the dynamic logger and the accompanying application program. For example, the individual that loads and/or configures the dynamic logger or application program, the user of the application program, etc.

The term log statement will be used throughout this description to mean the lines of code which are inserted by the developer into the application program (e.g., in the various source code files of the application program) to monitor the application program. An example of a log statement will be provided below. The term log report will be used throughout this description to mean the output of the exemplary embodiments of the dynamic logger according to the present invention. Those of skill in the art will understand that this output in the log reports may be based on the information contained in the log statements. The log reports may be output via one or more devices in one or more formats. Exemplary devices and formats will be described in greater detail below.

Exemplary software code is included throughout this description. This software code is only used to provide examples of manners in which the described exemplary embodiment may be implemented in software code. Those of skill in the art will understand that there may be any number of manners of software coding using various programming languages to implement the exemplary embodiments of the present invention.

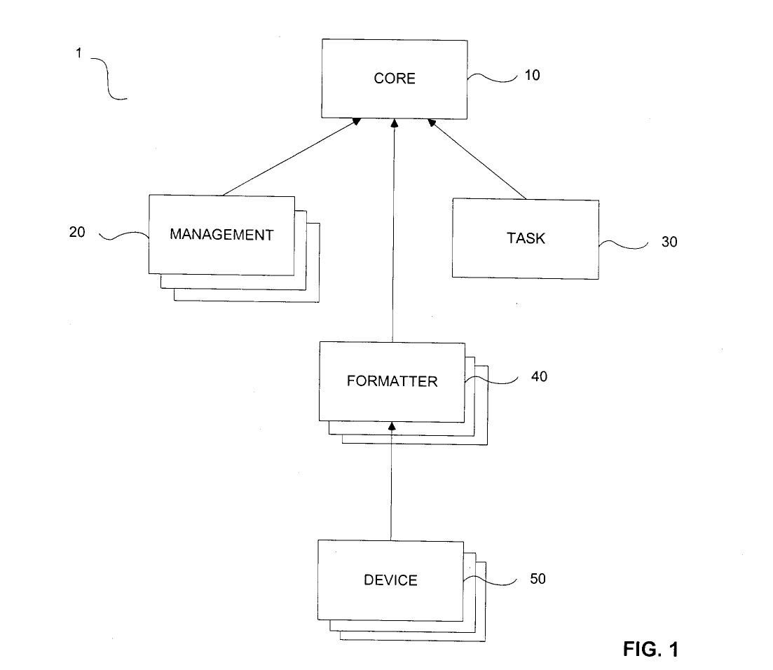

FIG. 1 shows an exemplary embodiment of a dynamic logger system 1 including the components 10-50. The dynamic logger 1 may be used to log messages for a specific system or application program. The core component 10 is a framework into which the remaining components 20-50 may be plugged-in, if desired. Thus, the core component 10 is the only essential component of the dynamic logger 1 according to the exemplary embodiment of the present invention. The remaining components 20-50 may be optional. This arrangement for the dynamic logger 1 results in a modular configuration where features (e.g., components 20-50) may be plugged-in to the dynamic logger 1 to vary the image or functionality of the dynamic logger 1. In addition, the modular nature of the dynamic logger 1 allows the developer the ability to trade-off between the features included in the dynamic logger 1 and the memory footprint of the dynamic logger 1. Each developer may make an individual determination based on the application and device.

It should be understood and will be described in greater detail below that each of components 20-50 may be multiple components. For example, the developer using dynamic logger 1 may desire to have the log output formatted in multiple formats. In such a case, the developer may plug in multiple formatter components 40 to achieve the multiple formats. Thus, each of components 20-50 may be understood to be (n) components 20-50, where (n) is the number of like components plugged-in by the developer.

The core component 10 may include any amount of logger functionality. For example, the core component 10 may have a minimal amount of logger functionality to provide a basic set of logger functions. In a further example, the core component 10 may not include any logger functionality beyond the ability to provide a plug-in location for the other components 20-50. This may be desirable when the dynamic logger 1 is to be provided for an embedded device where there may be a limited amount of memory space (i.e., no logger functionality in the core component 10 results in a smaller memory footprint for the component). The core component 10 is transparent to the operating system on which the dynamic logger 1 is implemented. The core component 10 may be made operating system transparent by not including any operating system calls in the core component 10. Thus, the dynamic logger 1 is not limited to any particular operating system and may be transported to any operating system.

In the exemplary embodiment of the dynamic logger 1, the log statements and reports may be separated by group and level. Each group may define a portion or portions of the application program for which a particular log statement may be active and each level may determine the severity at which a log report entry will be generated. Those of skill in the art will understand that the following examples of groups and levels are only exemplary and that a developer may define any groups and/or levels. The developer may define and include any number of groups and/or levels of log statements in the application program. As will be described in greater detail below, the modular configuration of the exemplary embodiment of the dynamic logger 1 allows for the dynamic configuration of the log statements at both compile-time and run-time. This dynamic configuration feature allows for the log statements included in the application program to be turned on and/or off by the developer.

The group may be based on the application program and be related to a portion or portions of the application program. For example, a first group of log statements may be related to the startup of the application program and a second group of log statements may be related to the shutdown of the application program. Each of these groups of log statements is definable by the developer and may be included in the source code of the application program. Thus, the developer, when inserting a log statement into the source code of the application program, may insert a log statement associated with a particular group. Other examples of groups may be a test group, a communication group, a protocol group (e.g., TCP/IP), a graphical user interface (“GUI”) group, etc. The developers may define the groups based on the needs of the particular application program.

Using the above example of the startup group, when the developer inserts a log statement into a portion of the source code that relates to the startup of the application program, the developer may insert a log statement defined in the group startup. As will become apparent from this description, the defined group of the log statement may be used by the dynamic logger 1 to control the operation of this log statement. The following is an exemplary general format of a log statement which may be included in the application program:

LOG_BLOCK (GROUP ( LEVEL(
{
LOG (“format string”, p0, p1, p2, p3, p4, p5);
} )));

In this exemplary general format, the log statement includes the group (GROUP) and level (LEVEL) definition for the log statement, a state definition (LOG) for the log statement, a log message (format string) and six parameters (p0 . . . p5) for the log message. The state definition for the log statements may be used to determine if the log statement should use the current thread (i.e., the application program thread) or a deferred thread (e.g., the dynamic logger thread). In this example, a deferred thread may be used by including the code statement LOG_DEFERRED, rather than the code statement LOG. Thread selection will be discussed in more detail below. The log message may be, for example, the text that will be reported in the log report for this log statement and may include the defined parameters.

The following is a specific example of a log statement using the exemplary general format described above:

LOG_BLOCK (LG_STARTUP (LL_INFO (
{
char *fmt = “The task %s is using %d bytes of memory”;
char *task = “sysMonitor”
int mem = 4500;
LOG (fmt, task, mem, 0, 0, 0, 0);
})));

In this example, the defined group for the log statement is the startup group (LG_STARTUP). The defined level for the log statement is an information level (LL_INFO). The levels will be described in greater detail below. The log statement is defined to use the current thread (LOG), the log message is defined by the string (fmt) which has two parameters, task and mem within the log message. The remaining parameters are set to null. Thus, the above exemplary log statement may be inserted by the developer into the source code of the application program at a location relating to the startup of the application program.

Those of skill in the art will understand that an application program may have tens or hundreds of source code files and that there may be multiple source code files which relate to the same defined groups (e.g., startup, shutdown, communication, etc.) and/or a single source code file which relates to multiple groups. The exemplary embodiment of the dynamic logger 1 can handle each of these situations. For example, log statements from a particular group (e.g., startup, shutdown, communication, etc.) may be inserted into multiple source code files. In addition, log statements from multiple groups may be inserted into the same source code files. It should also be understood that a log statement group may include one or more log statements, i.e., the exemplary log statement above may be only one of many log statements which are included in the startup group. Additional log statements may also be included in the startup group. These additional log statements may include any one or more of different levels, different states, different log messages and/or different parameters.

The level of a log statement defines the severity of the event that the log statement is monitoring within the application program. Similar to the groups described above, the levels may be defined by the developer to encompass a wide range of log report severity for the log statements. For example, the developer may define levels such as an information level, a debugging level, a warning level, an error level, etc. As can be seen from the names of the exemplary levels, the developer may categorize the severity of the log statement. A log statement having a level of information may produce a log report showing informational data. For example, the above exemplary log statement indicates the amount of memory used by a particular task of the application program. The log report from this log statement may be thought of providing the developer with specific information about the application program as it is executed and therefore, logically belongs in the information level.

Continuing with the exemplary levels described above, a log statement which provides the developer with a log report indicating that the application program has failed may be considered to be an error level. Thus, such a log statement may be categorized by the developer in the error level. Those of skill in the art will understand that these levels are only exemplary and the individual developer may define any number of levels of severity based on the needs of the particular application program.

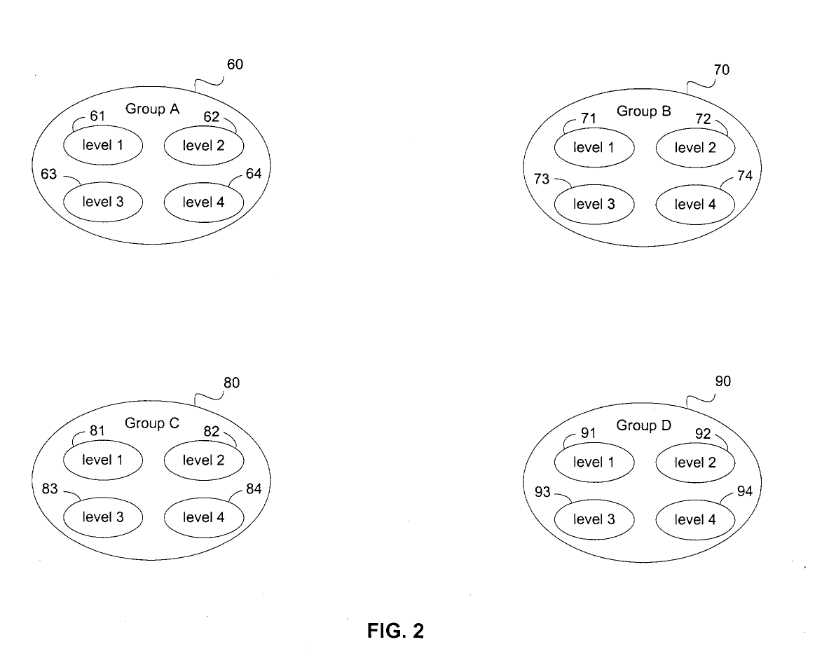

Each log statement is associated with a group and a level (e.g., the above exemplary log statement is associated with the startup group and the information level). FIG. 2 shows an exemplary logical categorization of exemplary groups and levels for log statements. In this example the developer has determined that there are four logical groups of log statements and has defined these four groups as Group A 60, Group B 70, Group C 80 and Group D 90. The developer has also determined and defined four levels of severity for the log statements in each of these groups, e.g., Group A 60 having Levels 1-4 61-64, Group B 70 having Levels 1-4 71-74, Group C 80 having Levels 1-4 81-84, and Group D 90 having Levels 1-4 91-94. The levels may be commonly defined across the four groups 60, 70, 80, 90, i.e., the severity Level 1 61 for Group A 60 is the same severity as Level 1 81 for Group C 80.

The levels may also be defined in a hierarchical manner. For example, Level 1 61 may be the lowest level of severity, Level 2 62 the next highest level of severity, Level 3 63 the next highest level of severity and Level 4 64 the highest level of severity. In such a hierarchical arrangement, it may be possible to selectively turn log statements on and off based on the severity level. For example, the developer may determine that in a particular stage of development, the developer only wants to see log reports with a Level 3 63 or higher severity. Thus, the developer may turn on the log statements having a Level 3 63, which may also automatically turn on the higher severity log statements, e.g., Level 4 64 log statements. The turning on and off of log statements will be described in greater detail below.

The preceding description described and provided examples of log statements and the contents of log statements which may be included by developers in the application program to provide log reports upon the execution of the application program. Thus, a developer, having defined the groups and levels of log statements may insert the various log statements in the application program as needed. The following will describe and provide examples of the process the developer may use to define the various groups and levels.

Those of skill in the art will understand that it may not be necessary for the developer to define any groups and/or levels because the dynamic logger 1 may include predefined groups and levels. For example, the core component 10 of the dynamic logger 1 may be pre-loaded with a set of default groups and levels that the developer may use without the need for defining new levels and/or groups. However, the ability to include developer defined groups and levels in the dynamic logger 1 allows for greater flexibility when using the dynamic logger 1.

A custom group and/or level may be defined using a macro. The macro may be included, for example, in a header file (e.g., myApp_logConfig.h). The use of this header file will be described in greater detail below. An exemplary macro may be used to define a custom group called “test” which the developer desires to create for a specific application program. The exemplary macro may include an include file which may be the default header for the dynamic logger 1. The include file may contain the definitions for any default groups and/or levels. Thus, by including the default header in the custom macro, any default groups and/or levels may also be accessed in addition to the custom groups and/or levels defined by the developer (e.g., the custom group “test”).

The macro may also include the log domain into which the newly defined group is to be registered. An exemplary name for a log domain may be myApp_logDomain. The log domain will be described in greater detail below. The macro may also include an indication of the function which will be used to register the custom group. An exemplary name for the registration function may be myApp_logInit( ). The registration function will also be described in greater detail below. The macro may then define the specific operation of the group “test” in the event that the group is turned on by the developer.

The log domain is the name of the location into which the custom groups and/or levels may be defined by the developer. The following exemplary code provides an example of the setup for the exemplary log domain called myApp_logDomain to carry through with the example started above:

```
#include<logger/ws_log_lib.h>
#include<myApp_logConfig.h>
int myApp_logDomain = 0
char*myApp_logGroups[] =
{
    “test”,
    NULL
};
```

In this example, the first include file is the core logger header file which may be included in the core component 10 of the dynamic logger 1. The second include file is the header file <myApp_logConfig.h> which includes the definition for the custom group “test” (e.g., in the form of the macro described above) and any default groups and/or levels provided by the dynamic logger 1. The code goes on to define the log groups to be registered in the log domain myApp_logDomain. The variable myApp_logGroups is then set equal to all the custom groups which are to be registered in the log domain myApp_logDomain. In this example, the only custom group to be registered in the log domain myApp_logDomain is the group “test”.

Thus, at this point in the coding, the developer has defined the custom groups and/or levels which are to be defined for the application program and has registered these custom groups and/or levels in an appropriate log domain. The developer may then initialize the custom groups and/or levels from the log domain by calling the appropriate initialization function in the application program. For example, as described above in the exemplary macro, the developer may define an initialization function myApp_logInit( ) for the log domain(s) (e.g., myApp_logDomain) which are defined for the dynamic logger 1. Exemplary software code for the initialization function may be as follows:

void myApp_logInit( )
{
myApp_logDomain = ws_log_domain_register(“myApp”,
myApp_logGroups,NULL);
}

In this example, the initialization function myApp_logInit( ) calls an application programming interface (“API”) ws_log_domain_register for the myApp_log domain. The API may be included in the core component 10 of the dynamic logger 1. The call to the API actually initializes the custom groups and/or levels for use in the application program. The exemplary API has three arguments, the name of the log domain, the variable defining the custom groups and the variable defining the custom levels. In this example, the name of the log domain is “myApp”, the variable defining the custom groups is myApp_logGroups which is defined above in the exemplary code for the log domain and the variable defining the custom levels is NULL because there were no custom levels defined in this example. Thus, a developer may include a call to the initialization function myApp_logInit in the startup of the application program to initialize the custom groups and/or levels in the log domain myApp_logDomain for use in the log statements which are included in the application program.

The preceding example was limited to the description of defining, registering and initializing a single custom group called “test” in the log domain “myApp”. However, those of skill in the art will understand that the preceding example may be used to define and register any number of custom groups into the log domain “myApp” or into any other log domain which the developer may create. In addition, multiple log domains my be created and initialized for a single application program. Furthermore, the developer may use the same procedure to define and register custom levels into the log domain “myApp” or any other log domain.

Referring back to FIG. 1, the formatter component 40 and the device component 50 will be described. As described above, the formatter component 40 and the device component 50 may actually be a series of components that are plugged into the core component 10. The formatter components 40 may be any manner of formatting the log report which may be generated by the log statements inserted into the application program. Exemplary formatter components may include a hypertext markup language (“HTML”) formatter, a text string formatter, a plain text formatter, a binary formatter, an ASCII formatter, a text delimited formatter, etc. The formatter components 40 determine the format of the log reports generated by the log statements. For example, if an HTML formatter component 40 is plugged-in and selected for use by the developer, the format of the log report will be in HTML. The developer's selection of formatter components 40 and device components 50 will be described in greater detail below.

The dynamic logger 1 is designed to support any formatter components 40 which may be written by a developer. Thus, the provider of dynamic logger 1 may include default formatter components 40 which the developer may use and/or the developer may write custom formatter components 40 to customize the format of the log reports as necessary for the particular application program. Additionally, since the formatter components 40 are plug-ins, the developer only needs to plug-in those formatter components 40 which are intended to be used. Thus, not all of the possible formatter components 40 need to be plugged-in to the dynamic logger 1, thereby reducing the memory footprint of the dynamic logger 1 to include only those formatter components 40 which are intended for use.

The device components 50 may be any manner of outputting the log report to the developer. Exemplary device components may include a file, a printer, a standard I/O, a socket, etc. The device components 50 determine the physical location of the log reports generated by the log statements. For example, if a printer is selected to be the device component 50, the log report will be printed to the selected printer.

A stream is the combination of a formatter component 40 and a device component 50. For example, the developer may select a stream that is comprised of an HTML formatter 40 and a file component 50. Thus, a log report sent to this stream will be formatted in HTML and directed to a file. The file may then be displayed, for example, as a web page because it has been formatted in HTML. Referring to FIG. 1, the device component 50 is shown with an arrow to the formatter component 40 which then is shown pointing to the core component 10. It should be understood that both the formatter component 40 and the device component 50 are plugged-in to the core component 10. The depiction in FIG. 1 indicates that the formatter component 40 and the device component 50, in combination, form a stream for the dynamic logger 1.

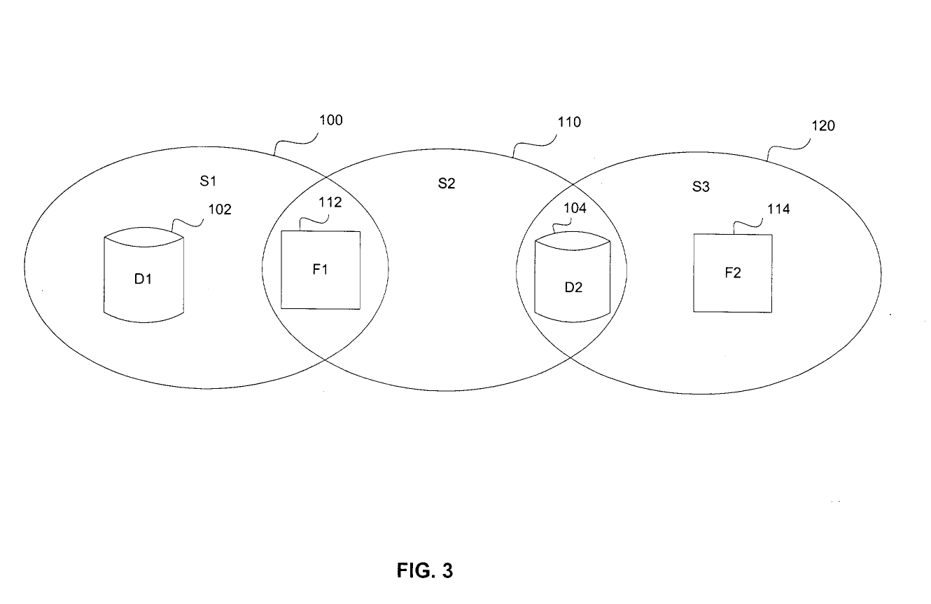

A single instance of a formatter component 40 and/or a device component 50 may be used in multiple streams. FIG. 3 shows a diagram illustrating the use of a single instance of formatter components and device components to build multiple streams. In this example, there are three streams, S1 100, S2 110 and S3 120. The stream S1 100 is comprised of device D1 102 and formatter F1 112. The stream S2 110 is comprised of device D2 104 and formatter F1 112. The stream S3 120 is comprised of device D2 104 and formatter F2 114. Thus, the single instance of formatter F1 112 is used in streams S1 100 and S2 110. For example, the formatter F1 112 may be a text string formatter and the log reports formatted in such a manner may be output to both of devices D1 102 and D2 104. Similarly, the single instance of the device D2 104 is used in streams S2 110 and S3 120.

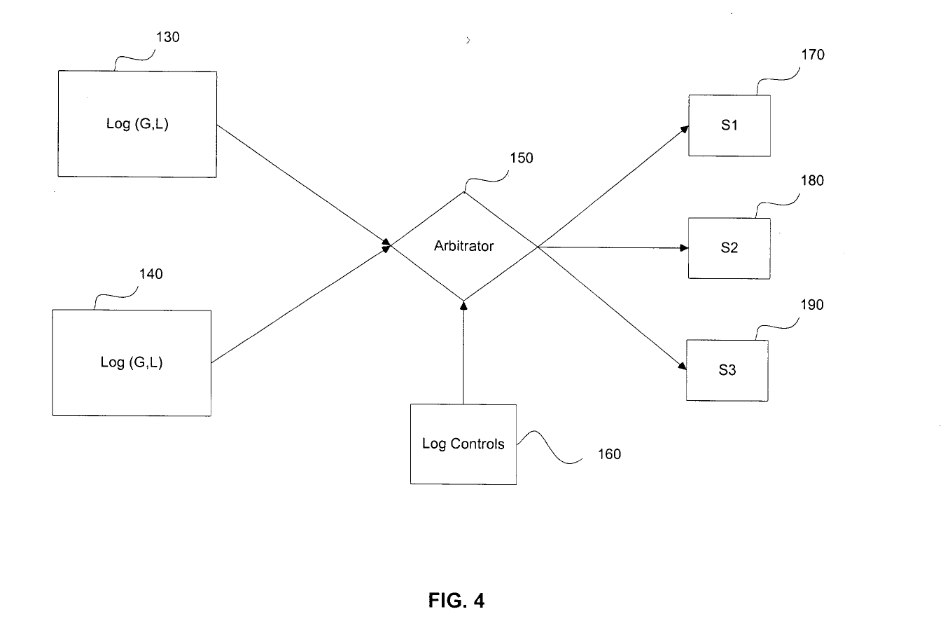

When two or more streams use the same device component 50, the dynamic logger 1 will arbitrate between the two streams so that the log statements (log reports) for the different streams do not become entangled. FIG. 4 shows an exemplary system for arbitrating between log statements and streams. In FIG. 4 there are two exemplary log statements 130, 140, an arbitrator 150, log controls 160 and three output streams 170, 180 and 190. It may be considered in this example that stream S1 170 and stream S2 180 share the same instance of a device component (e.g., a file). It may also be considered that the log report from log statement 130 should be directed to stream S1 170 and the log report from log statement 140 should be directed to stream S2 180. Thus, the log reports for both the log statements 130 and 140 will be directed to the same device component.

The core component 10 of the dynamic logger 1 may contain the arbitrator 150 which can arbitrate between the two streams such that the log reports from the log statements do not become entangled. The developer, via the log controls 160, may determine the priority for the two streams. As will be described in greater detail below, the log controls may be data which is entered by the developer to control the operation of the dynamic logger 1. For example, the developer may determine that the higher severity levels of the log statements are to receive priority for the streams. In a further example, the developer may determine that a particular group is to receive priority over other groups. In this example, each of the log statements 130, 140 include a group and level. Thus, when the log statements are received by the core component 10 at the arbitrator 150, the core component 10 may determine the priority of the log statements and arbitrate between the streams sharing the device component. Further functionality of the arbitrator 150 will be discussed in greater detail below.

Referring back to FIG. 1, the task component 30 may be included so that the log statement tasks may be queued and run on a deferred thread, i.e., the dynamic logger 1 thread. The core component 10 includes functionality which allows for the dynamic logger 1 tasks to run in the current thread, i.e., the application program thread. In the first instance, it would be preferred if the dynamic logger 1 functions were to be carried out on the current thread because it would save processor and memory overhead on actions such as context switching. However, in some instances, for example, when the current thread is handling an interrupt, it may not be possible to execute the dynamic logger 1 functionality on the current thread. In these instances, a deferred task component 30 plug-in allows for the functions to be queued and executed at a later time so as not to interfere with the main line processing of the application program. The developer may select to include the deferred task component 30 plug-in based on the individual application program.

The management component 20 may be a series of plug-in components which provide management functions for the dynamic logger 1. The management component 20 may allow for any known interface with the dynamic logger 1 (e.g., a web based graphical user interface (“GUI”), a Windows® GUI, a command line interface (“CLI”), etc.). The developer may interact with the management interface of the management component 20 to select the functionality for the dynamic logger 1. The management component 20 plug-ins may provide various types of management functions. For example, the management component 20 may provide a manner of defining the groups and levels as described above, e.g., a graphical manner for building the code for custom groups and levels. A further example may allow for the developer to graphically select the various components and plug them into the core component 10. In a further example, the management component 20 may allow the developer to select various formatter components 40 and device components 50 in order to create and initialize streams. Those of skill in the art will understand there are any number of functions which may be carried out by various management component 20 plug-ins.

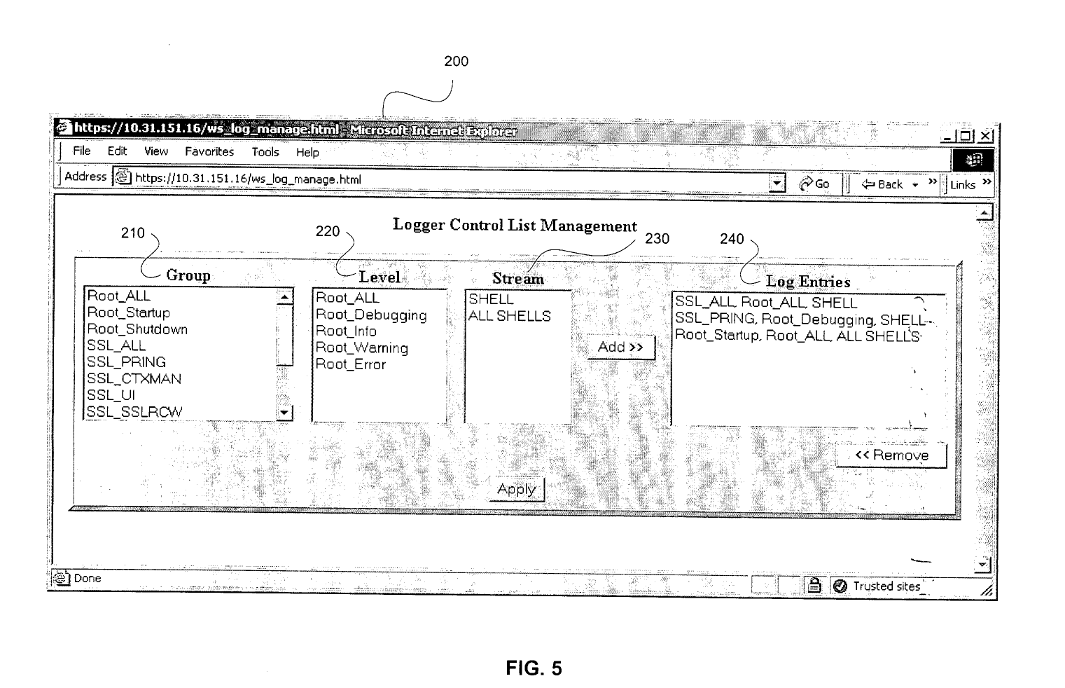

FIG. 5 shows an exemplary management component 20 plug-in which provides a management interface 200 for configuring the dynamic logger 1. In this example, the management interface 200 is a GUI interface which allows the developer to selectively turn log statements on and off and to select the streams into which the log reports for the log statements are sent. The result of these selections by the developer using the management interface 200 is the creation of a log entry. The log entry then controls the operation of the dynamic logger 1 with respect to the processing of log statements and the directing of the log reports to the appropriate stream. The terms log entry and log controls may be used interchangeably in this description to describe this control of the operation of the dynamic logger 1.

In this example, the management interface has a group field 210, a level field 220, a stream field 230 and a log entry field 240 which shows the resulting log entry after it is created by the developer. The group field 210 shows all the groups that have been created and registered in the various log domains. In this example, groups are shown as being registered in two log domains, the Root domain and the SSL domain (indicated, in this example, by using the prefixes “Root” and “SSL” appended to each group name). It may be considered that the Root domain is the default domain containing the default groups and the SSL domain is a domain created by the developer and containing custom groups defined and registered by the developer according to, for example, the procedure described above. In this example, the Root domain contains the groups Startup, Shutdown and ALL, where ALL signifies a combination of all the default groups, e.g., Startup and Shutdown. The SSL domain contains the groups ALL, PRING, CTXMAN, UI, SSLRCW (and some additional groups that will be shown if the developer uses the scroll bar on the side of the group field 210).

The level field 220 shows that the Root domain contains five default levels: ALL, Debugging, Info, Warning and Error. The developer has not registered any custom levels in this example. The stream field 230 shows that the developer has created two streams SHELL and ALL SHELLS. As described above, each stream is the combination of a formatter component 40 and a device component 50. Thus, in this example, the developer has defined two unique combinations of formatter component(s) 40 and device component(s) 50 into streams SHELL and ALL SHELLS.

The developer may now create log entries using the management interface 200. For example, the developer created the first log entry by selecting the SSL_ALL group from the group field 210, selecting the Root_ALL level from the level field 220 and selecting the SHELL stream from the stream field 230 and adding it to the log entry field 240. Thus, the first log entry is SSL_ALL, Root_ALL, SHELL. This log entry means that the developer has turned on all groups of log statements registered in the log domain SSL, regardless of the log statement level and the log reports are to be directed to the stream SHELL. When the application program is executed, the log statements associated with this log entry will be activated and the log reports will be output to the appropriate stream. As described above, the stream will format the log report and send the formatted log report to the appropriate output device.

In a further example, the developer created the second log entry by selecting the SSL_PRING group from the group field 210, selecting the Root_Debugging level from the level field 220 and selecting the SHELL stream from the stream field 230 and adding it to the log entry field 240. Thus, the second log entry is SSL_PRING, Root_Debugging, SHELL. This log entry means that the developer has turned on the log statements in the custom group PRING having a level of Debugging (or higher) and directed the log reports to the stream SHELL. When the application program is executed, the log statements associated with this log entry will be activated and the log reports will be output to the appropriate stream.

Referring back to FIG. 4, the arbitrator 150 of the dynamic logger 1 determines the stream into which a log report should be directed. The log entries created by the developer on the management interface 200 may be the log controls 160 that are accessed by the arbitrator 150 to determine the operation of the dynamic logger 1. The log controls 160 may be kept in the form of a list or table of all the groups, levels and streams which have been entered into log entries so that when a log statement is executed by the application program, the dynamic logger 1 performs the appropriate action. For example, when log statement 130 is executed by the application program, the log statement 130 will be passed to the arbitrator 150. The arbitrator 150 will compare the group and level of the log statement 130 to the log controls 160 (e.g., the table of log entries) and send the log report to the appropriate stream for the log report to be formatted and output.

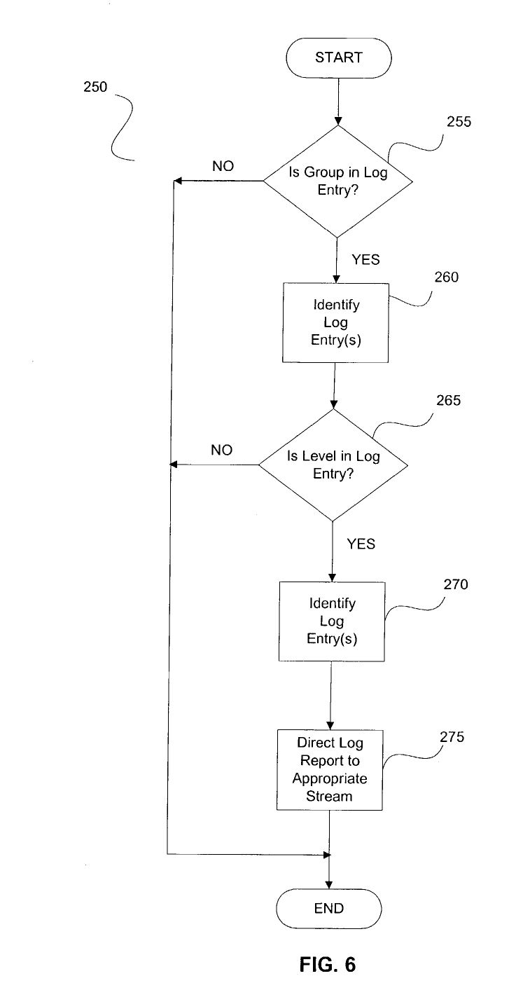

FIG. 6 shows an exemplary method 250 for the arbitrator 150 to direct the log reports to the appropriate stream. The exemplary method 250 will be described using an example of the log entries shown in FIG. 5 and the diagram of FIG. 4. In the example, the log statement 130 may be considered to be in the group SSL_UI and have a level of Info. Thus, when the log statement 130 is executed within the code of the application program, the arbitrator 150 receives the log statement 130 which includes the group and level of the log statement. In step 255 of the method, the arbitrator 150 compares the group to which the log statement 130 belongs (e.g., SSL_UI) to the log entries entered by the developer. As described above, the log entries may be stored in a data structure such as a table, a list, an array, etc., which may be accessed by the arbitrator 150. If the group of the log statement 130 does not match any groups in the log entries, the process ends because the developer has configured the dynamic logger 1 such that no log report has been requested for this particular log statement.

Those of skill in the art will understand that if the developer has configured the dynamic logger 1 such that the current log statement is not active, this code may not be executed by the application program, i.e., a variable or other coding contained in the log statement (which is in the application program) may be undefined such that it is not executed with the application program. Thus, it may not be the arbitrator 150 which determines that a particular log statement group is not in the active log entries, but rather, those log statements which are not included in active log entries may never be executed in the application program code. The setting of log statement(s) active or inactive may occur at compile time.

In this example, the group of the log statement is in a log entry, i.e., the group SSL_UI is included in the SSL_ALL group as shown in the first log entry in the log entry field 240 of FIG. 5. In step 260, the arbitrator 150 identifies the log entries having a group which matches the group of the current log statement. Those of skill in the art will understand that in step 260 the arbitrator 150 may identify multiple log entries having a group which matches the group of the current log statement 130. In other words, the steps 255 and 260 may be carried out in an iterative manner where the arbitrator 150 looks at multiple log entries to determine each of the log entries which match the group of the current log statement. In this example, there is only one log entry which matches the group of the log statement 130, i.e., the SSL_ALL group as shown in the first log entry in the log entry field 240.

The process continues to step 265 where it is determined whether the level of the current log statement 130 matches the levels included in the log entries identified in step 260. If the level of the current log statement 130 does not match the level in any of the log entries identified in step 260, the process ends because the developer has configured the dynamic logger 1 such that no log report is requested for this particular log statement. In this example, the level of the current log statement 130 is in the log entry identified in step 260, i.e., the level Info is included in the Root_ALL levels as shown in the first log entry in the log entry field 240. Therefore, the process continues to step 270 where the arbitrator 150 identifies all the log entries having a group and level match for the current log statement. Once again, the arbitrator 150 may identify multiple log entries having group and level matches for the current log statement 130. Those of skill in the art will understand that the arbitrator 150 may query each log entry one at a time in steps 255-270, i.e., determine if there is a group match for the current log entry, determine if there is a level match for the current log entry and then go to the next log entry. However the process is performed, the result is that all the log entries which match the group and level of the current log statement will be identified. In this example, there is only one log entry which matches the group and level of the current log statement 130, i.e., the log entry having the group SSL_ALL and the level Root_ALL match the current log statement 130 having the group SSL_UI and the level Info.

The process then continues to step 275 where the arbitrator directs the log report for the log statement to the appropriate stream. As described above, the arbitrator has identified all the log entries which match the group and level for the current log statement. Thus, the arbitrator may then look at the appropriate log entries and determine the stream to which the log report should be sent. In the current example, the log entry that matches the group and level of the current log statement 130 is the first log entry shown in the log entry field 240 of FIG. 5. Thus, the arbitrator may identify the stream from this log entry, i.e., SHELL, and send the log report to this stream. As described previously, the stream will then format the log report and send the formatted log report to the appropriate output device. If there had been multiple log entries identified in step 270, the arbitrator would have directed the log report to each of the streams as identified in the log entries.

As described above, the arbitrator 150 may also arbitrate based on the priority levels of groups and levels. Similar to the log entries described above, additional entries may be entered by the developer which define the rankings of the groups and levels. The arbitrator may then use these log entries in the same manner as described above to send the log reports to the appropriate stream in the desired hierarchy.

The description of the management interface 200 showed a method by which the developer can build log entries. These log entries may be built at compile time and at run time of the application program. Thus, the developer has the ability to turn log statements on and off and direct them to various output devices at both compile time and run time. If the developer is only interested in the log statements related to the startup of the application program, the developer may create a log entry which turns on only those log statements in a group related to the startup. However, when the startup has been completed, the developer may then be interested in the log statements related to the shutdown of the application program. The developer may then create a log entry which turns on the log statements in a group related to the shutdown of the application program. However, in the exemplary embodiment of the dynamic logger 1, the developer may create this new log entry and turn the shutdown log statements on at run time without recompiling the application program because the log statements were already included in the application program by the developer. The dynamic logger 1 simply allows these log statements to be turned on and off.

The system and method of the present invention may include set of instructions which may be stored on a computer-readable storage medium. The set of instructions may be capable of being executed by a processor to perform the functions of the exemplary embodiment of the dynamic logger 1 described above. An example of an instruction set being executed by a processor may include the steps of receiving a log statement from an application program, the log statement including a group identifier and a level identifier, accessing a log control which includes a group, a level and an output stream, comparing the group identifier and level identifier of the log statement to the corresponding group and level of the log control and directing a log report generated from the log statement to the output stream when the group of the log control includes the group identifier of the log statement and the level of the log control includes the level identifier of the log statement.

In the preceding specification, the present invention has been described with reference to specific exemplary embodiments thereof. It will, however, be evident that various modifications and changes may be made thereunto without departing from the broadest spirit and scope of the present invention as set forth in the claims that follow. The specification and drawings are accordingly to be regarded in an illustrative rather than restrictive sense.

What is claimed is:

1. A logger system, comprising:
a core component configured to receive a log statement from an application program, the log statement including a group identifier and a level identifier, the core component further configured to direct a log report generated from the log statement to an output stream based on the group identifier and the level identifier of the log statement and log controls accessible to the core component.

2. The logger system according to claim 1, further comprising:
a management component plugged into the core component and configured to present an interface to a developer to configure the system.

3. The logger system according to claim 2, wherein the developer inputs the log controls via the management component.

4. The logger system according to claim 3, wherein the developer inputs the log controls during the run-time execution of the application program.

5. The logger system according to claim 2, wherein the management component is a graphical user interface.

6. The logger system according to claim 1, wherein the output stream includes:
a formatter component plugged into the core component and configured to format the log report; and
a device component plugged into the core component and configured to output the log report to a specified location.

7. The logger system according to claim 6, wherein the formatter component includes one of an HTML formatter, a text string formatter, a plain text formatter, a binary formatter, an ASCII formatter, and a text delimited formatter.

8. The logger system according to claim 6, wherein the device component includes one of a file, a printer, a standard 1/O, and a socket.

9. The logger system according to claim 1, wherein the log controls include a log entry which includes a group, a level and the output stream and wherein the core component directs the log report to the output stream when the group of the log entry includes the group identifier of the log statement and the level of the log entry includes the level identifier of the log statement.

10. The logger system according to claim 1, wherein the core component operations occur in a same execution thread as the application program.

11. The logger system according to claim 1, further comprising:
a task component plugged into the core component and configured to allow the core component operations to occur in a different execution thread than the application program.

12. The logger system according to claim 11, wherein the core component operations are stored in a queue while the application program thread is executing.

13. The logger system according to claim 1, wherein the group identifier and the level identifier is definable by a developer.

14. A method comprising the steps of:
receiving a log statement from an application program, the log statement including a group identifier and a level identifier;
accessing a log control which includes a group, a level and an output stream;
comparing the group identifier and level identifier of the log statement to the corresponding group and level of the log control; and
directing a log report generated from the log statement to the output stream when the group of the log control includes the group identifier of the log statement and the level of the log control includes the level identifier of the log statement.

15. The method according to claim 14, further comprising:
inserting additional log controls when the application program is executing; and
repeating the above steps for the additional log controls.

16. The method according to claim 14, wherein the output stream includes a formatter component and a device component.

17. The method according to claim 14, wherein the method steps are performed in a same execution thread as the application program.

18. A system, comprising:
a log control component including log entry data, wherein each log entry includes a group, a level and an output stream; and
an arbitrator component receiving a log statement from an application program, the log statement including a group identifier and a level identifier, the arbitrator accessing each log entry and directing a log report generated from the log statement to the output stream of each log entry for which the group of the log entry includes the group identifier of the log statement and the level of the log entry includes the level identifier of the log statement.

19. The system according to claim 18, wherein each output stream includes a formatter component and a device component.

20. The system according to claim 18, wherein a single instance of the formatter component is included in multiple output streams.
